(19) United States
(12) Patent Application Publication
(10) Pub. No.: US 2006/0126416 A1
(43) Pub. Date: Jun. 15, 2006

(54) Memory cell array structure adapted to maintain substantially uniform voltage distribution across plate electrode

(76) Inventors: Dong-Myung Eun, Seoul (KR); Soo-Bong Chang, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/280,405

(22) Filed: Nov. 17, 2005

(30) Foreign Application Priority Data
Dec. 14, 2004 (KR) 2004-105315

(51) Int. Cl. G11C 5/14

(52) U.S. Cl. 365/226

(57) ABSTRACT

Disclosed is a wiring structure for supplying a plate electrode voltage to a memory device comprising a plurality of memory cells. The wiring structure includes a first plurality of metal wires arranged in a first direction along peripheral and center portions of a plate electrode and a second plurality of metal wires arranged on the first metal wires in a second direction intersecting the first direction. The second metal lines are connected to the first metal wires via first electrical contacts and the first metal lines are connected to the plate electrode via second electrical contacts.

### BACKGROUND OF THE INVENTION

1. Field of the Invention

The present invention relates generally to a memory cell array having a plate electrode. More particularly, the invention relates to a memory cell array structure adapted to maintain a substantially uniform electrical potential across the plate electrode.

A claim of priority is made to Korean Patent Application No. 10-2004-0105315 filed on Dec. 14, 2004, the disclosure of which is hereby incorporated by reference in its entirety.

2. Description of Related Art

Dynamic Random Access Memory (DRAM) is commonly used to provide temporary data storage in electronic devices such as personal computers. A typical DRAM comprises a plurality of memory cells arranged in a memory cell array. In the memory cell array, each memory cell stores a bit of data using a capacitor, and the logic state of each memory cell is determined by the number of electrons present on the capacitor. For example, FIG. 1 illustrates a conventional memory cell used in a DRAM.

Referring to FIG. 1, the conventional memory cell comprises a capacitor “C” having an upper electrode 11 and a lower electrode 12, and an access transistor “Ta” having a first terminal connected to a bitline BL, a second terminal connected to upper electrode 11, and a gate connected to a wordline WL.

Data is written to the conventional memory cell by applying a wordline signal to wordline WL with a logic state “high” to turn on access transistor “Ta” and then applying a bitline signal to bitline BL. Where the bitline signal has a logic state “high”, electrons accumulate on upper electrode 11 to represent a logical “1”. Otherwise, where the bitline signal has a logic state “low”, upper electrode 11 accumulates no electrons to represent a logical “0”.

Data is read from the conventional memory cell by applying the wordline signal to wordline WL with logic state “high” to turn on access transistor “Ta” and then sensing and measuring the amount of charge on upper electrode 11 through bitline BL to determine the logic state of the memory cell. A sense amplifier connected to bitline BL generally senses and measures the amount of charge on upper electrode 11.

Because upper electrode 11 is used to store electrical charges, it is referred to as a storage electrode. Lower electrode 12, on the other hand, is used to provide a reference voltage “Vp” for the electrical charges stored on upper electrode 11. The reference voltage provided by lower electrode 12 generally has a value between the voltage levels of logic state “high” and logic state “low”. For example, where the voltage level of logic state “high” is a power supply voltage “Vcc” and the voltage level of logic state “low” is ground, the voltage level of reference voltage “Vp” is typically Vcc/2. As a result, where bitline BL has logic state “low”, electrons gravitate away from upper electrode 11 and toward the lower electrical potential; where bitline BL has logic state “high”, electrons gravitate toward the lower electrical potential of upper electrode 11.

Because the voltage level of lower electrode 12 is presumably constant, memory cell arrays often use a plate electrode to supply reference voltage Vp to several memory cells at a time for lower electrode 12. Accordingly, reference voltage Vp may be referred to as a plate electrode voltage.

FIGS. 2A and 2B illustrate two conventional memory architectures wherein multiple memory cells use the same plate electrode to provide reference voltage Vp. FIG. 2A shows a folded bitline architecture 210 and FIG. 2B shows an open bitline architecture 220.

In folded bitline architecture 210, complementary bitlines BL and /BL are arranged in parallel on one side of a sense amplifier 211 and in open bitline architecture 220, complementary bitlines BL and /BL are arranged on opposite sides of a sense amplifier 221.

The bitlines in folded bitline architecture 210 and open bitline architecture 220 are connected to a plurality of memory cells such as the one shown in FIG. 1 and the plurality of memory cells are connected to plate electrodes supplying reference voltage Vp. The plate electrodes are typically formed of a single plate poly layer connected to a single power source providing reference voltage Vp.

As the number of memory cells using the same plate electrode increases, the size of the plate electrode must increase accordingly. Unfortunately, increasing the size of the plate electrode can cause the plate poly layer to have an uneven voltage distribution due to resistance in the plate poly layer. As a result the reference voltage provided to the memory cells can be different depending on their relative positions on the plate electrode. In particular, in the open bitline architecture, since complementary bitlines BL and /BL are located on opposite sides of sense amplifier 221, noise affecting the plate electrodes or peripheral signal line couplings will be different for each of the complementary bitlines. As a result, corresponding memory cells may not operate correctly. In other words, unpredictability in the reference voltages of the memory cells can lead to unstable operation of the DRAM.

### SUMMARY OF THE INVENTION

According to one embodiment of the invention, a memory cell array structure comprises a plurality of memory cells formed in a memory cell area, a first layer acting as a plate electrode for the plurality of memory cells, formed over a top surface of the memory cell area, a first plurality of metal lines formed in a first direction along peripheral and center portions of the first layer and coupled to the first layer by respective first contacts, and a second plurality of metal lines formed in a second direction intersecting the first direction on the first metal lines and coupled to the first metal lines at intersections by respective second contacts.

According to another embodiment of the invention, a memory cell array structure comprises a plurality of memory cells formed in a memory cell area comprising a normal memory cell area and a dummy memory cell area, a first layer acting as a plate electrode for the plurality of memory cells, formed over a top surface of the memory cell area, a first plurality of metal lines formed in a first direction along peripheral and center portions of the first layer and coupled to the first layer by respective first contacts, and a second plurality of metal lines formed in a second direction intersecting the first direction on the first metal lines and coupled to the first metal lines at intersections by respective second contacts. The dummy memory cell is located beneath the first plurality of metal lines formed along the center portion of the first layer.

According to still another embodiment of the invention, a memory device comprises a plurality of memory cells formed in a plurality of memory cell array areas, each having a separate plate electrode layer, a plurality of word line enable signal lines formed in a first direction in each of the respective plate electrode layers to deliver respective word line enable signals to the gates of access transistors in the plurality of memory cells, and a first plurality of plate power lines formed in the first direction along peripheral and center portions of the respective plate electrode layers and respectively coupled to the plate electrode layers by first contacts.

According to still another embodiment of the invention, a method of supplying a plate electrode voltage to a plate electrode in a memory device is provided. The memory device comprises a plurality of memory cells located in a memory cell area, and plate electrode layer formed over a top side of the memory cell area and acting as the plate electrode, and the method comprises applying the plate electrode voltage to metal lines along center and peripheral portions of the plate electrode.

According to still another embodiment of the invention, a structure adapted to supply a plate electrode voltage to a plurality of memory cells in a semiconductor memory device is provided. Each memory cell comprises a capacitor having an upper electrode and a lower electrode operatively connected to a plate electrode voltage generator, and an access transistor having a first terminal connected to a bitline, a second terminal connected to the upper terminal of the capacitor, and a gate connected to a wordline. The structure comprises a plurality of wiring lines forming a mesh structure on a plate electrode layer acting as the lower electrode for the capacitors in the plurality of memory cells.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

Figure (FIG.) 1 is a circuit diagram of a conventional DRAM cell;

FIG. 2A is a block diagram of a memory cell array having a folded bitline structure;

FIG. 2B is a block diagram of a memory cell array having an open bitline structure;

FIG. 3 illustrates a layout for a memory cell array structure according to one embodiment of the present invention;

FIG. 4 is a cross-sectional view taken along a line between points A and A′ in FIG. 3;

FIG. 5 illustrates a layout for a memory cell array structure according to another embodiment of the present invention; and,

FIG. 6 is a block diagram of a memory device having the memory cell array structure shown in FIG. 3 or 5.

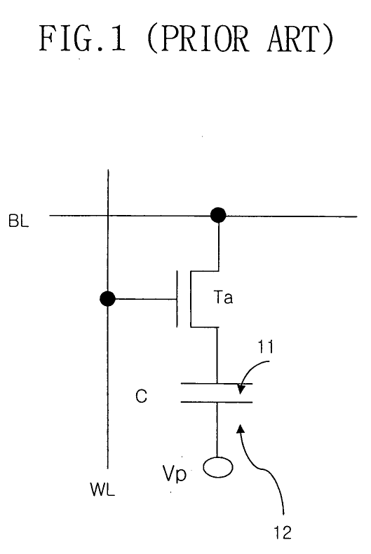

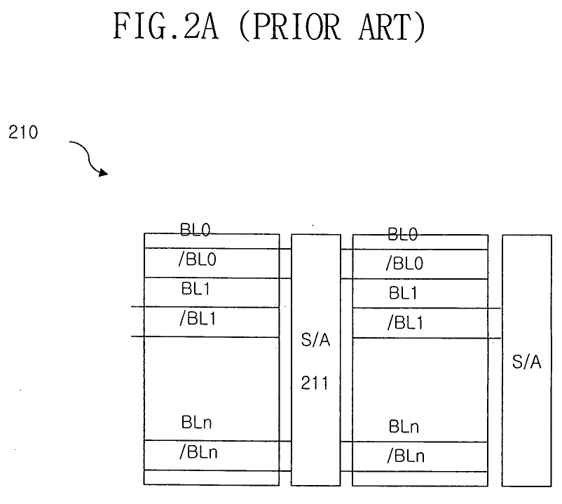

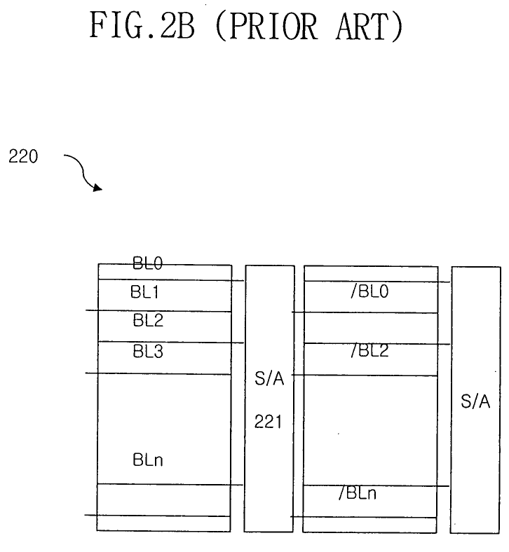

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

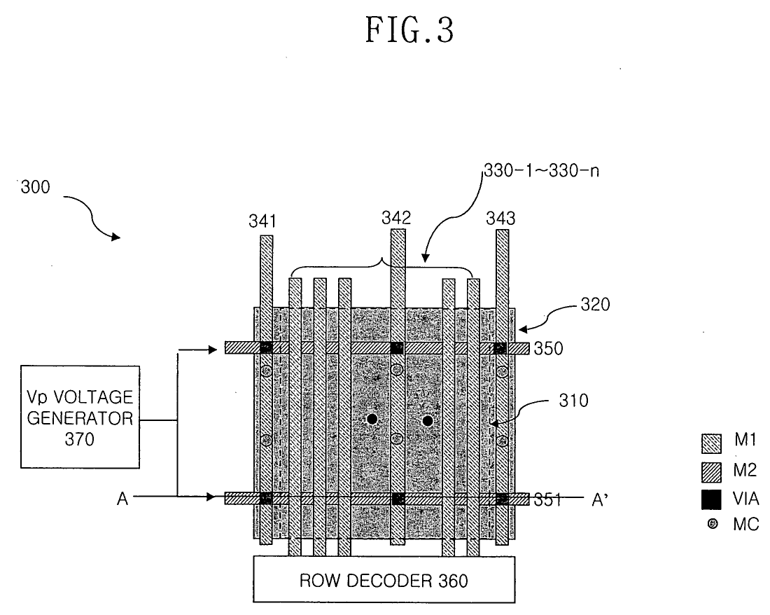

FIG. 3 illustrates a layout for a memory cell array structure according to an embodiment of the present invention.

Referring to FIG. 3, a memory cell array structure 300 comprises a memory cell array area 310 denoted by a broken box, a plate electrode layer 320, a plurality of word line enable lines 330-1 through 330-n, and a plurality of plate electrode power lines 341, 342, 343, 350 and 351. Memory cell array structure 300 is also connected to a row decoder 360 and a plate electrode voltage generator 370.

Memory cell array area 310 includes a plurality of memory cells such as the one shown in FIG. 1. Plate electrode layer 320 is formed over an entire surface of memory cell array area 310 to serve as a plate electrode for capacitors in the plurality of memory cells.

Word line enable lines 330-1 through 330-n are formed in memory cell area 310 by a first metal layer M1. Word line enable lines 330-1 through 330-n receive word line enable signals from row decoder 360 to control the gates of the access transistors in the plurality of memory cells. Word line enable signal lines 330-1 through 330-n are formed over plate electrode layer 320 and are separated from plate electrode layer 320.

Plate power lines 341, 342, 343, 350 and 351 include first plate power lines 341, 342 and 343 arranged in a first direction and second plate power lines 350 and 351 arranged in a second direction intersecting the first direction.

First plate power lines 341, 342 and 343 are formed of first metal layer M1 and include plate power lines 341 and 343 located at edges of plate electrode layer 320 and plate power line 342 located at a center portion of the plate electrode layer. First plate power lines 341, 342 and 343 are coupled to plate electrode layer 320 via a plurality of first contacts denoted “MC contacts”.

Second plate power lines 350 and 351 are formed of a second metal layer M2 and are arranged in the second direction to intersect first plate power lines 341, 342 and 343 on a different layer. Second plate power lines 350 and 351 are supplied with a plate electrode voltage Vp from plate electrode voltage generator 370. They deliver plate electrode voltage Vp to first plate power lines 341, 342 and 343 via a plurality of second contacts denoted “VIA contacts”. The second plate power lines are typically formed by second metal layer M2 on top of first metal layer M1.

In memory cell array structure 300, since plate electrode voltage Vp is supplied to the central portion of the plate electrode layer and to both edges of the plate electrode layer, the distribution of plate electrode voltage Vp across plate electrode 320 will be relatively uniform compared to the distribution of the plate electrode voltage Vp in a conventional memory cell array structure. As a result, the operation of the memory cells in the memory cell array structure will be more stable.

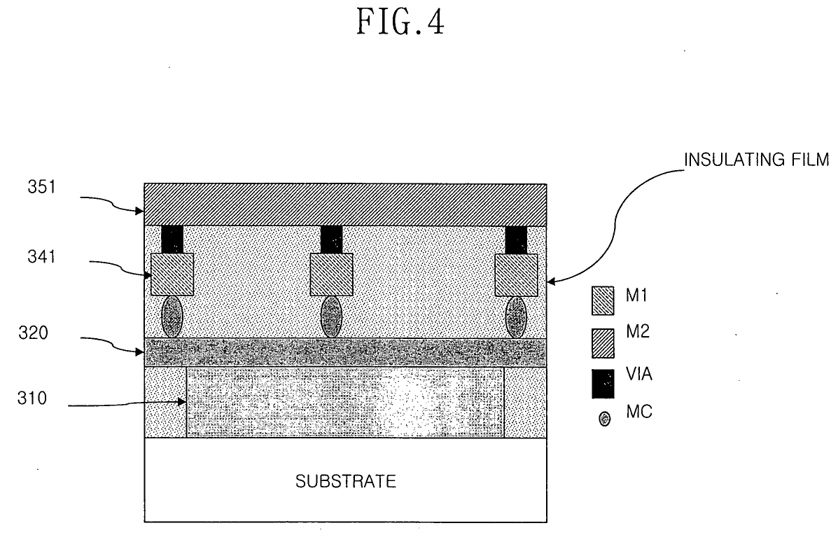

FIG. 4 is a cross-sectional view of the memory cell array structure shown in FIG. 3 taken along a line between points A and A′ in FIG. 3. The purpose of FIG. 4 is to illustrate a vertical relationship between elements in the memory array shown in FIG. 3.

Referring to FIG. 4, plate electrode layer 320 is integrally formed over an entire surface of memory cell array area 310. Memory cell array 310 comprises a plurality of memory cells formed on a substrate. Plate electrode 320 is typically formed of a polysilicon material commonly referred to as “plate poly”. MC contacts are formed at edges and at a center portion of plate electrode layer 320 within an insulating film. First plate voltage supply lines 341, 342 and 343 are formed of a first metal layer M1 and are electrically connected with plate electrode layer 320 through the MC contacts.

Via contacts are formed on first plate voltage supply lines 341, 342 and 343 to electrically connect these lines to second plate voltage supply line 351 formed by second metal layer M2.

The first and second plate voltage supply lines form a mesh structure over the memory cell array as can be seen in FIGS. 3 and 4. Accordingly, voltage variation across plate electrode layer 320 due to resistance and peripheral noise is minimized.

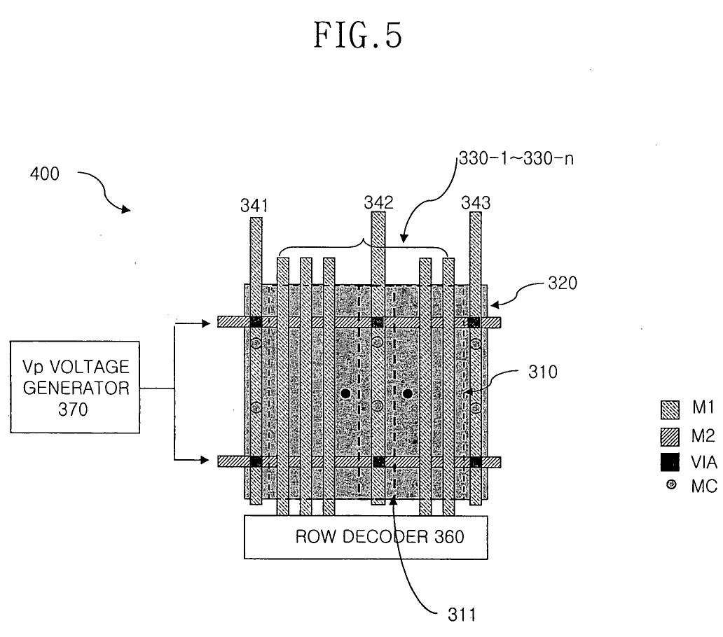

FIG. 5 illustrates a layout for a memory cell array structure according to another embodiment of the present invention. The layout shown in FIG. 5 is substantially the same as that shown in FIG. 3, except that the layout of FIG. 5 further comprises a dummy memory cell area 311 in a center portion of memory cell area 310.

In the layout shown in FIG. 3, the MC contact at the center portion of memory cell array area 310 is formed together with MC contacts at peripheral portions of memory cell array area 310. In the layout of FIG. 5, the center MC contact is still formed at the same time as the peripheral MC contacts, even though dummy memory cell area 311 is formed in the center portion of memory cell area 310.

Dummy memory cell area 311, which includes several dummy memory cells, is formed beneath a portion of memory cell array area where MC contacts are to be formed. The MC contacts are formed above the dummy memory cells at the same time that MC contacts are formed in peripheral areas of memory cell area 310.

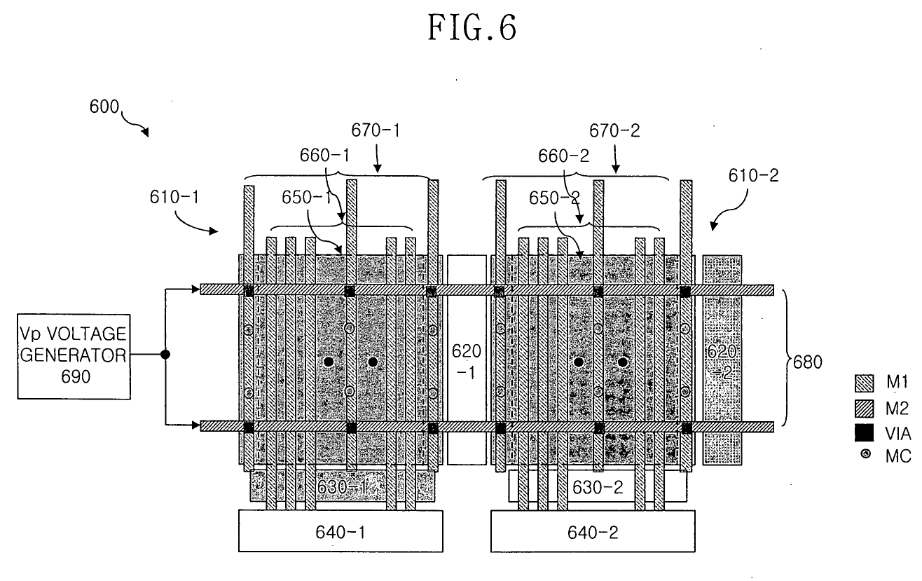

FIG. 6 illustrates a partial layout of a memory device having the memory cell array structure of FIG. 3 or 5.

Referring to FIG. 6, a memory device 600 comprises a plurality of memory cell array blocks 610-1 and 610-2, sense amplifier blocks 620-1 and 620-2 formed on respective right sides of the memory cell array blocks, sub word line driver blocks 630-1 and 630-2 formed beneath the respective memory cell array blocks, and row decoders 640 and 641 formed at respective bottom sides of memory cell array blocks 610-1 and 610-2. Memory device 600 further comprises plate electrode layers 650-1 and 650-2, main word line enable signal lines 660-1 and 660-2 formed over the plate electrode layers, first plate electrode power lines 670-1 and 670-2, second plate electrode power lines 680, and a plate electrode voltage generator 690.

Plate electrode layers 650-1 and 650-2 are integrally formed over top sides of respective memory cell arrays 610-1 and 610-2.

Main word line enable signal lines 660-1 and 660-2 are formed of a first metal layer M1 extending in a first direction from corresponding row decoders 640-1 and 640-2. Main word line enable signal lines 660-1 and 660-2 are formed over plate electrode layers 650-1 and 650-2 and are separated from plate electrode layers 650-1 and 650-2 by a space. In addition, main word line enable signal lines 660-1 and 660-2 are electrically connected to sub word line blocks 630-1 and 630-2 and to gates of access transistors (not shown) of the respective memory cells.

First plate electrode power lines 670-1 and 670-2 are formed of first metal layer M1 in a first direction and are disposed on left and right edges and center portions of plate electrode layers 650-1 and 650-2. In addition, first plate electrode power lines 670-1 and 670-2 are coupled to plate electrode layers 650-1 and 650-2 via MC contacts.

Second plate electrode power lines 680 are formed of a second metal layer M2 in a second direction intersecting the first direction and are disposed to intersect first plate electrode power lines 670-1 and 670-2 on the left and right edges and the center portions of respective plate electrode layers 650-1 and 650-2. Second plate electrode power lines 680 are electrically connected to first plate electrode power lines 670-1 and 670-2 by “via contacts” at the intersections thereof.

Plate electrode voltage generator 690 supplies a plate electrode voltage to second plate electrode power lines 680.

In the memory device shown in FIG. 6, plate electrode power lines are formed in center and peripheral portions of plate electrode layers. This arrangement of plate electrode power lines creates a substantially uniform voltage distribution across the plate electrode layers to minimize the possibility of device malfunctions that may be caused in the memory device due to erroneous reference voltages.

In the memory device of FIG. 6, the memory cell array structure of FIG. 5 can be substituted for the memory cell array structure of FIG. 3.

Although the foregoing embodiments of the invention show plate electrode power lines arranged on peripheral and center portions of the plate electrode layers, the positioning of the plate electrode power lines can change without departing from the scope of this invention.

The foregoing preferred embodiments are teaching examples. Those of ordinary skill in the art will understand that various changes in form and details may be made to the exemplary embodiments without departing from the scope of the present invention which is defined by the following claims.

What is claimed:

1. A memory cell array structure, comprising:
a plurality of memory cells formed in a memory cell area;
a first layer acting as a plate electrode for the plurality of memory cells, formed over a top surface of the memory cell area;
a first plurality of metal lines formed in a first direction along peripheral and center portions of the first layer and coupled to the first layer by respective first contacts; and,
a second plurality of metal lines formed in a second direction intersecting the first direction on the first metal lines and coupled to the first metal lines at intersections by respective second contacts.

2. The memory cell array structure of claim 1, further comprising:
a plate electrode voltage generator formed adjacent to the memory cell area to supply a plate electrode voltage to the second plurality of metal lines.

3. The memory cell array structure of claim 1, wherein the first contacts are MC contacts and the second contacts are via contacts.

4. The memory cell array structure of claim 1, further comprising:
a plurality of word line enable signal lines formed over the plate electrode layer in the first direction.

5. The memory cell array structure of claim 4, wherein the word line enable signal lines are respectively attached to respective gates of access transistors in the plurality of memory cells.

6. The memory cell array structure of claim 2, wherein the first and second pluralities of metal lines supply the plate electrode voltage to the plate electrode.

7. A memory cell array structure, comprising:
a plurality of memory cells formed in a memory cell area comprising a normal memory cell area and a dummy memory cell area;
a first layer acting as a plate electrode for the plurality of memory cells, formed over a top surface of the memory cell area;
a first plurality of metal lines formed in a first direction along peripheral and center portions of the first layer and coupled to the first layer by respective first contacts; and,
a second plurality of metal lines formed in a second direction intersecting the first direction on the first metal lines and coupled to the first metal lines at intersections by respective second contacts.
wherein the dummy memory cell located beneath the first plurality of metal lines formed along the center portion of the first layer.

8. The memory cell array structure of claim 7, further comprising:
a plate electrode voltage generator formed adjacent to the memory cell area to supply a plate electrode voltage to the second plurality of metal lines.

9. The memory cell array structure of claim 7, wherein the first contacts are MC contacts and the second contacts are via contacts.

10. The memory cell array structure of claim 7, further comprising:
a plurality of word line enable signal lines formed over the plate electrode layer in the first direction.

11. The memory cell array structure of claim 10, wherein the word line enable signal lines are attached to respective gates of access transistors in the plurality of memory cells.

12. The memory cell array structure of claim 8, wherein the first and second pluralities of metal lines supply the plate electrode voltage to the plate electrode.

13. A memory device comprising:
a plurality of memory cells formed in a plurality of memory cell array areas, each having a separate plate electrode layer;
a plurality of word line enable signal lines formed in a first direction in each of the respective plate electrode layers to deliver respective word line enable signals to the gates of access transistors in the plurality of memory cells; and,
a first plurality of plate power lines formed in the first direction along peripheral and center portions of the respective plate electrode layers and respectively coupled to the plate electrode layers by first contacts.

14. The memory device of claim 13, further comprising:
a plate electrode voltage generator formed adjacent to the memory cell area and adapted to generate the plate electrode voltage; and,
a second plurality of plate power lines formed in a second direction intersecting the first direction and coupled to the first plurality of plate power lines by second contacts;
wherein the plate electrode voltage generator supplies the plate electrode voltage to the plate electrode layers through the first and second pluralities of plate power lines.

15. The memory device of claim 13, wherein each of the memory cell areas comprises:
a dummy memory cell area formed beneath the first plurality of plate power lines formed along the center portion of the plate electrode layer.

16. A method of supplying a plate electrode voltage to a plate electrode in a memory device comprising a plurality of memory cells located in a memory cell area, and plate electrode layer formed over a top side of the memory cell area and acting as the plate electrode, the method comprising:
applying the plate electrode voltage to metal lines along center and peripheral portions of the plate electrode.

17. A structure adapted to supply a plate electrode voltage to a plurality of memory cells in a semiconductor memory device, wherein each memory cell comprises:
a capacitor having an upper electrode and a lower electrode operatively connected to a plate electrode voltage generator; and,
an access transistor having a first terminal connected to a bitline, a second terminal connected to the upper terminal of the capacitor, and a gate connected to a wordline;
the structure comprising:
a plurality of wiring lines forming a mesh structure on a plate electrode layer acting as the lower electrode for the capacitors in the plurality of memory cells.

18. The structure of claim 17, wherein the wiring lines comprise metal lines arranged in a first direction in a first layer and in a second direction intersecting the first direction on a second layer.

19. The structure of claim 18, wherein the metal lines in the first layer are formed in parallel along peripheral and center portions of the plate electrode layer and are coupled to the metal lines in the second layer by electrical contacts.

20. The structure of claim 18, further comprising:
a plurality of word line enable signal lines formed over the plate electrode layer in the first direction.
